(19) United States
(12) Patent Application Publication
(10) Pub. No.: US 2019/0122945 A1
(43) Pub. Date: Apr. 25, 2019

(54) METHOD FOR PRODUCING HERMETIC PACKAGE, AND HERMETIC PACKAGE

(71) Applicant: Nippon Electric Glass Co., Ltd., Otsu-shi, Shiga (JP)

(72) Inventors: Toru SHIRAGAMI, Shiga (JP); Takuji OKA, Shiga (JP)

(73) Assignee: Nippon Electric Glass Co., Ltd., Otsu-shi, Shiga (JP)

(21) Appl. No.: 16/092,571

(22) PCT Filed: Mar. 22, 2017
(86) PCT No.: PCT/JP2017/011489

§ 371 Date: Oct. 10, 2018

(30) Foreign Application Priority Data
Apr. 11, 2016 (JP) 2016-078643

(51) Int. Cl. H01L 23/10; C04B 35/581; C04B 37/04

(52) U.S. Cl. CPC H01L 23/10; C04B 35/581; C04B 37/045; H01L 33/483; C04B 2237/70; H01L 2933/0033; C04B 2237/121

(57) ABSTRACT

A method of producing a hermetic package of the present invention includes the steps of: preparing an aluminum nitride base, and forming a sintered glass-containing layer on the aluminum nitride base; preparing a glass cover, and forming a sealing material layer on the glass cover; arranging the aluminum nitride base and the glass cover so that the sintered glass-containing layer and the sealing material layer are brought into contact with each other; and irradiating the sealing material layer with laser light from a glass cover side to soften and deform the sealing material layer, to thereby hermetically seal the sintered glass-containing layer and the sealing material layer with each other to obtain a hermetic package.

### TECHNICAL FIELD

The present invention relates to a method of producing a hermetic package comprising hermetically sealing an aluminum nitride base and a glass cover with each other through sealing treatment using laser light (hereinafter referred to as “laser sealing”).

### BACKGROUND ART

In a hermetic package having mounted therein an ultraviolet LED device, aluminum nitride is used as a material for a base from the viewpoint of thermal conductivity, and glass is used as a material for a cover from the viewpoint of light transmissivity in an ultraviolet wavelength region.

An organic resin-based adhesive having a low-temperature curing property has hitherto been used as an adhesive material for an ultraviolet LED package. However, the organic resin-based adhesive is liable to be degraded with light in the ultraviolet wavelength region, and there is a risk in that the airtightness of the ultraviolet LED package may be reduced with time. In addition, when gold-tin solder is used instead of the organic resin-based adhesive, the degradation with light in the ultraviolet wavelength region can be prevented. However, the gold-tin solder has a problem of having high material cost.

Meanwhile, a sealing material containing glass powder has the advantages of being less liable to be degraded with light in the ultraviolet wavelength region and having low material cost.

However, the glass powder has a higher softening temperature than the organic resin-based adhesive, and hence there is a risk in that the ultraviolet LED device may be thermally degraded at the time of sealing. Under such circumstances, laser sealing has attracted attention. According to the laser sealing, only a portion to be sealed can be locally heated, and an aluminum nitride base and a glass cover can be hermetically sealed with each other without thermal degradation of the ultraviolet LED device.

### CITATION LIST

Patent Literature 1: JP 2013-239609 A
Patent Literature 2: JP 2014-236202 A

### SUMMARY OF INVENTION

### Technical Problem

According to investigations made by the inventors of the present invention, a sealing material containing bismuth-based glass sufficiently reacts with an object to be sealed at the time of laser sealing, and hence laser sealing strength can be increased. A sealing material containing any other glass does not sufficiently react with the object to be sealed at the time of laser sealing, and hence it is difficult to ensure laser sealing strength.

Meanwhile, the sealing material containing bismuth-based glass tends to generate bubbles at an interface with aluminum nitride through a reaction with aluminum nitride. Therefore, when the aluminum nitride base and the glass cover are laser sealed with each other through use of the sealing material containing bismuth-based glass, there is a risk in that airtightness cannot be ensured owing to the bubbles in a sealing material layer. Further, there is a risk in that also the mechanical strength of a hermetic package cannot be ensured owing to the bubbles.

Thus, the present invention has been made in view of the above-mentioned circumstances, and a technical object of the present invention is to devise a method for suppressing bubbles in a sealing material layer and increasing laser sealing strength in the case of laser sealing an aluminum nitride base and a glass cover with each other.

### Solution to Problem

The inventors of the present invention have made extensive investigations, and as a result, have found that the above-mentioned technical object can be achieved by performing laser sealing under a state in which a sintered glass-containing layer intermediates between an aluminum nitride base and a sealing material layer. Thus, the finding is proposed as the present invention. That is, a method of producing a hermetic package according to one embodiment of the present invention comprises the steps of: preparing an aluminum nitride base, and forming a sintered glass-containing layer on the aluminum nitride base; preparing a glass cover, and forming a sealing material layer on the glass cover; arranging the aluminum nitride base and the glass cover so that the sintered glass-containing layer and the sealing material layer are brought into contact with each other; and irradiating the sealing material layer with laser light from a glass cover side to soften and deform the sealing material layer, to thereby hermetically seal the sintered glass-containing layer and the sealing material layer with each other to obtain a hermetic package.

In the method of producing a hermetic package according to the embodiment of the present invention, after the sintered glass-containing layer is formed on the aluminum nitride base, the sintered glass-containing layer is arranged so as to be brought into contact with the sealing material layer on the glass cover, and laser sealing is performed under this state. With this, the sealing material layer is less liable to be brought into contact with the aluminum nitride base, and hence bubbles are less liable to be generated in the sealing material layer at the time of laser sealing. Further, both the sealing material layer and the sintered glass-containing layer contain low-melting-point glass, and hence the layers satisfactorily react with each other at the time of laser sealing. Thus, laser sealing strength can be increased.

Secondly, in the method of producing a hermetic package according to the embodiment of the present invention, a width of the sintered glass-containing layer is preferably larger than a width of the sealing material layer. With this, the sealing material layer is less liable to be brought into contact with the aluminum nitride base, and hence the bubbles in the sealing material layer are easily prevented.

Thirdly, in the method of producing a hermetic package according to the embodiment of the present invention, a ratio of (thickness of the sintered glass-containing layer)/(thickness of the sealing material layer) is preferably controlled to 0.5 or more. With this, heat is less liable to be dissipated through the aluminum nitride base at the time of laser sealing, and hence the efficiency of the laser sealing can be improved.

Fourthly, in the method of producing a hermetic package according to the embodiment of the present invention, a ratio of (thermal expansion coefficient of the sintered glass-containing layer)/(thermal expansion coefficient of the aluminum nitride base) is preferably controlled to 0.6 or more and 1.4 or less. With this, cracks and the like are less liable to occur at an interface between the sintered glass-containing layer and the aluminum nitride base. Herein, the “thermal expansion coefficient” refers to a value measured with a push-rod type thermal expansion coefficient measurement (TMA) apparatus in a temperature range of from 30° C. to 300° C.

Fifthly, in the method of producing a hermetic package according to the embodiment of the present invention, the forming a sintered glass-containing layer preferably comprises forming a glass-containing film on the aluminum nitride base, followed by irradiating the glass-containing film with laser light to sinter the glass-containing film. With this, thermal degradation of electrical wiring or a light emitting device in the aluminum nitride base is easily prevented.

Sixthly, in the method of producing a hermetic package according to the embodiment of the present invention, it is preferred that the aluminum nitride base to be used comprise a base part and a frame part formed on the base part, and the sintered glass-containing layer be formed on a top of the frame part. With this, a light emitting device, such as an ultraviolet LED device, is easily housed in the hermetic package.

Seventhly, the method of producing a hermetic package according to the embodiment of the present invention preferably further comprises a step of polishing a surface of the sintered glass-containing layer. With this, adhesiveness between the sintered glass-containing layer and the sealing material layer is increased, and hence the accuracy of the laser sealing can be improved.

Eighthly, a hermetic package according to one embodiment of the present invention comprises an aluminum nitride base and a glass cover, wherein the aluminum nitride base comprises a base part and a frame part formed on the base part, wherein the aluminum nitride base has formed, on a top of the frame part thereof, a sintered glass-containing layer substantially free of bismuth-based glass, wherein the glass cover has formed thereon a sealing material layer containing bismuth-based glass and refractory filler powder, and wherein the sintered glass-containing layer and the sealing material layer are hermetically integrated with each other under a state in which the sintered glass-containing layer and the sealing material layer are arranged so as to be brought into contact with each other.

In the hermetic package according to the embodiment of the present invention, the sintered glass-containing layer substantially free of bismuth-based glass is formed on the top of the frame part of the aluminum nitride base, and the sealing material layer containing bismuth-based glass and refractory filler powder is formed on the glass cover. As compared to glasses based on other materials, the bismuth-based glass has the advantage of easily forming a reactive layer in a surface layer of an object to be sealed at the time of laser sealing, but has the drawback of excessively reacting with aluminum nitride to generate bubbles in the sealing material layer. In view of the foregoing, in the hermetic package according to the embodiment of the present invention, the sintered glass-containing layer is formed between the aluminum nitride base and the sealing material layer. With this, while reactivity between the sealing material layer and the sintered glass-containing layer at the time of laser sealing is increased, a situation in which bubbles are generated in the sealing material layer can be prevented. Further, through the intermediation of the sintered glass-containing layer, heat is less liable to be dissipated through the aluminum nitride base at the time of laser sealing, and hence also the efficiency of the laser sealing can be improved. The “bismuth-based glass” refers to glass comprising Bi₂O₃ as a main component, and specifically refers to glass comprising 25 mol % or more of Bi₂O₃ in a glass composition. The “sintered glass-containing layer substantially free of bismuth-based glass” refers to a sintered glass-containing layer having a content of Bi₂O₃ of less than 5 mol %.

Ninthly, in the hermetic package according to the embodiment of the present invention, a width of the sintered glass-containing layer is preferably larger than a width of the sealing material layer.

Tenthly, in the hermetic package according to the embodiment of the present invention, a ratio of (thickness of the sintered glass-containing layer)/(thickness of the sealing material layer) is preferably 0.5 or more.

Eleventhly, in the hermetic package according to the embodiment of the present invention, a ratio of (thermal expansion coefficient of the sintered glass-containing layer)/(thermal expansion coefficient of the aluminum nitride base) is preferably 0.6 or more and 1.4 or less.

Twelfthly, the hermetic package according to the embodiment of the present invention preferably has housed, inside the frame part of the aluminum nitride base, an ultraviolet LED device. Herein, the “ultraviolet LED device” includes a deep ultraviolet LED device.

### BRIEF DESCRIPTION OF DRAWINGS

FIG. 1 is a schematic view for illustrating a softening point of a sealing material measured with a macro-type DTA apparatus.

FIG. 2 is a conceptual sectional view for illustrating one embodiment of the present invention.

### DESCRIPTION OF EMBODIMENTS

A method of producing a hermetic package of the present invention comprises a step of preparing an aluminum nitride base and forming a sintered glass-containing layer on the aluminum nitride base. As a method of forming the sintered glass-containing layer on the aluminum nitride base, the following method is preferred: a method involving applying a glass-containing paste onto the aluminum nitride base to form a glass-containing film, followed by drying the glass-containing film to volatilize a solvent, and further, irradiating the glass-containing film with laser light to sinter (fix) the glass-containing film. With this, the sintered glass-containing layer can be formed without thermal degradation of electrical wiring or a light emitting device formed in the aluminum nitride base.

When the sintered glass-containing layer is formed through irradiation with laser light, a laser irradiation width is preferably larger than the width of the glass-containing film. With this, an unsintered portion is less liable to remain in the sintered glass-containing layer, and hence the surface smoothness of the sintered glass-containing layer is easily ensured.

The sintered glass-containing layer may be formed through firing of the glass-containing film, but in this case, from the viewpoint of preventing thermal degradation of the light emitting device or the like, the firing of the glass-containing film is preferably performed before mounting of the light emitting device or the like in the aluminum nitride base.

The sintered glass-containing layer is preferably formed of a sintered body of glass powder alone from the viewpoint of increasing the surface smoothness, but may be formed of a sintered body of composite powder containing the glass powder and refractory filler powder. Herein, as the glass powder, glass having low reactivity with the aluminum nitride base is preferred, and zinc-based glass powder (glass powder comprising 25 mol % or more of ZnO in a glass composition), alkali borosilicate-based glass powder, or the like is preferred. In addition, it is preferred not to use bismuth-based glass having high reactivity with the aluminum nitride base as the glass powder.

In the method of producing a hermetic package of the present invention, the thickness of the sintered glass-containing layer is preferably controlled to 50 μm or less or 30 μm or less, particularly preferably 15 μm or less. With this, cracks and the like resulting from a difference in thermal expansion coefficient between the sintered glass-containing layer and the aluminum nitride base are easily prevented.

The width of the sintered glass-containing layer is preferably larger than the width of the sealing material layer, and is more preferably larger than the width of the sealing material layer by 0.1 mm or more. When the width of the sintered glass-containing layer is smaller than the width of the sealing material layer, the sealing material layer is liable to be brought into contact with the aluminum nitride base, and hence bubbles are liable to be generated in the sealing material layer at the time of laser sealing.

The surface of the sintered glass-containing layer is preferably subjected to polishing treatment. In this case, the surface of the sintered glass-containing layer has a surface roughness Ra of preferably less than 0.5 μm or 0.2 μm or less, particularly preferably from 0.01 μm to 0.15 μm, and has a surface roughness RMS of preferably less than 1.0 μm or 0.5 μm or less, particularly preferably from 0.05 μm to 0.3 μm. With this, the adhesiveness between the sintered glass-containing layer and the sealing material layer is improved, and the accuracy of the laser sealing can be improved. As a result, the sealing strength of the hermetic package can be increased. The “surface roughness Ra” and “surface roughness RMS” may be measured with, for example, a contact-type or noncontact-type laser film thickness meter, or a surface roughness meter.

The thickness of the aluminum nitride base is preferably from 0.1 mm to 1.5 mm, particularly preferably from 0.5 mm to 1.2 mm. With this, thinning of the hermetic package can be achieved.

In addition, an aluminum nitride base comprising a base part and a frame part formed on the base part is preferably used as the aluminum nitride base, and the sintered glass-containing layer is preferably formed on a top of the frame part. With this, the light emitting device, such as an ultraviolet LED device, is easily housed inside the frame part of the aluminum nitride base.

When the sintered glass-containing layer is formed on the top of the frame part of the aluminum nitride base through irradiation with laser light, a laser light irradiation width is preferably smaller than the width of the frame part. With this, the glass-containing film is properly sintered at the time of laser irradiation, and besides, the light emitting device or the like inside the frame part is less liable to be damaged.

When the aluminum nitride base comprises the frame part, it is preferred to form the frame part on the aluminum nitride base along a peripheral end edge region thereof in a frame shape and apply the glass-containing film onto the top of the frame part. With this, the effective area for functioning as a device can be enlarged. In addition, the light emitting device, such as an ultraviolet LED device, is easily housed inside the frame part of the aluminum nitride base.

The method of producing a hermetic package of the present invention comprises a step of preparing a glass cover, and forming a sealing material layer on the glass cover.

The average thickness of the sealing material layer is preferably controlled to less than 10 μm or less than 7 μm, particularly preferably less than 5 μm. Similarly, the average thickness of the sealing material layer after the laser sealing is preferably controlled to less than 10 μm or less than 7 μm, particularly preferably less than 5 μm. As the average thickness of the sealing material layer is reduced more, a stress remaining in sealed sites after the laser sealing is reduced more even when the thermal expansion coefficient of the sealing material layer and the thermal expansion coefficient of the glass cover do not match each other sufficiently. In addition, also the accuracy of the laser sealing can be improved more. As a method of controlling the average thickness of the sealing material layer as described above, the following methods are given: a method involving thinly applying a sealing material paste; and a method involving subjecting the surface of the sealing material layer to polishing treatment.

The surface roughness Ra of the sealing material layer is controlled to preferably less than 0.5 μm or 0.2 μm or less, particularly preferably from 0.01 μm to 0.15 μm. In addition, the surface roughness RMS of the sealing material layer is controlled to preferably less than 1.0 μm or 0.5 μm or less, particularly preferably from 0.05 μm to 0.3 μm. With this, the adhesiveness between the sintered glass-containing layer and the sealing material layer is increased, and the accuracy of the laser sealing is improved. A method of controlling the surface roughnesses Ra and RMS of the sealing material layer as described above, the following methods are given: a method involving subjecting the surface of the sealing material layer to polishing treatment; and a method involving controlling the particle size of refractory filler powder.

The sealing material layer is formed of a sintered body of a sealing material. At the time of laser sealing, the sealing material layer is softened and deformed to react with the glass-containing layer. Various materials may be used as the sealing material. Of those, composite powder containing bismuth-based glass powder and refractory filler powder is preferably used from the viewpoint of ensuring laser sealing strength. In particular, as the sealing material, it is preferred to use a sealing material comprising 55 vol % to 95 vol % of bismuth-based glass and 5 vol % to 45 vol % of refractory filler powder. It is more preferred to use a sealing material comprising 60 vol % to 85 vol % of bismuth-based glass and 15 vol % to 40 vol % of refractory filler powder. It is particularly preferred to use a sealing material comprising 60 vol % to 80 vol % of bismuth-based glass and 20 vol % to 40 vol % of refractory filler powder. When the refractory filler powder is added, the thermal expansion coefficient of the sealing material easily matches the thermal expansion coefficients of the glass cover and the sintered glass-containing layer. As a result, a situation in which an improper stress remains in the sealed sites after the laser sealing is prevented easily. Meanwhile, when the content of the refractory filler powder is too large, the content of the bismuth-based glass is relatively reduced. Thus, the surface smoothness of the sealing material layer is decreased, and the accuracy of the laser sealing is liable to be decreased.

The bismuth-based glass preferably comprises as a glass composition, in terms of mol %, 28% to 60% of Bi₂O₃, 15% to 37% of B₂O₃, and 1% to 30% of ZnO. The reasons why the content range of each component is limited as described above are described below. In the description of the glass composition range, the expression “%” means “mol %”.

Bi₂O₃ is a main component for lowering a softening point, and its content is preferably from 28% to 60% or from 33% to 55%, particularly preferably from 35% to 45%. When the content of Bi₂O₃ is too small, the softening point becomes too high and hence flowability is liable to lower. Meanwhile, when the content of Bi₂O₃ is too large, the glass is liable to devitrify at the time of laser sealing, and owing to the devitrification, the flowability is liable to lower.

B₂O₃ is an essential component as a glass-forming component, and its content is preferably from 15% to 37% or from 20% to 33%, particularly preferably from 25% to 30%. When the content of B₂O₃ is too small, a glass network is hardly formed, and hence the glass is liable to devitrify at the time of laser sealing. Meanwhile, when the content of B₂O₃ is too large, the glass has an increased viscosity, and hence the flowability is liable to lower.

ZnO is a component which enhances devitrification resistance, and its content is preferably from 1% to 30%, from 3% to 25%, or from 5% to 22%, particularly preferably from 9% to 20%. When the content is less than 1%, or more than 30%, the glass composition loses its component balance, and hence the devitrification resistance is liable to lower.

In addition to the above-mentioned components, for example, the following components may be added.

SiO₂ is a component which enhances water resistance, while having an action of increasing the softening point. Accordingly, the content of SiO₂ is preferably from 0% to 5%, from 0% to 3%, or from 0% to 2%, particularly preferably from 0% to 1%. In addition, when the content of SiO₂ is too large, the glass is liable to devitrify at the time of laser sealing.

Al₂O₁ is a component which enhances the water resistance. The content of Al₂O₃ is preferably from 0% to 10% or from 0% to 5%, particularly preferably from 0.1% to 2%. When the content of Al₂O₃ is too large, there is a risk in that the softening point is inappropriately increased.

Li₂O, Na₂O, and K₂O are each a component which reduces the devitrification resistance. Therefore, the content of each of Li₂O, Na₂O, and K₂O is from 0% to 5% or from 0% to 3%, particularly preferably from 0% to less than 1%.

MgO, CaO, SrO, and BaO are each a component which enhances the devitrification resistance, but are each a component which increases the softening point. Therefore, the content of each of MgO, CaO, SrO, and BaO is from 0% to 20% or from 0% to 10%, particularly preferably from 0% to 5%.

In order to lower the softening point of Bi₂O₃-based glass, it is required to introduce a large amount of Bi₂O₃ into the glass composition, but when the content of Bi₂O₀ is increased, the glass is liable to devitrify at the time of laser sealing, and owing to the devitrification, the flowability is liable to lower. This tendency is particularly remarkable when the content of Bi₂O₃ is 30% or more. As a countermeasure for this problem, the addition of CuO can effectively suppress the devitrification of the glass even when the content of Bi₂O₁ is 30% or more. Further, when CuO is added, laser absorption characteristics at the time of laser sealing can be enhanced. The content of CuO is preferably from 0% to 40%, from 5% to 35%, or from 10% to 30%, particularly preferably from 15% to 25%. When the content of CuO is too large, the glass composition loses its component balance, and hence the devitrification resistance is liable to lower to the worse.

Fe₂O₃ is a component which enhances the devitrification resistance and the laser absorption characteristics, and its content is preferably from 0% to 10% or from 0.1% to 5%, particularly preferably from 0.5% to 3%. When the content of Fe₂O₃ is too large, the glass composition loses its component balance, and hence the devitrification resistance is liable to lower to the worse.

Sb₂O₃ is a component which enhances the devitrification resistance, and its content is preferably from 0% to 5%, particularly preferably from 0% to 2%. When the content of Sb₂O₃ is too large, the glass composition loses its component balance, and hence the devitrification resistance is liable to lower to the worse.

The glass powder preferably has an average particle diameter D₅₀ of less than 15 μm or from 0.5 μm to 10 μm, particularly preferably from 1 μm to 5 μm. As the average particle diameter D₅₀ of the glass powder is smaller, the softening point of the glass powder lowers.

As the refractory filler powder, one kind or two or more kinds selected from cordierite, zircon, tin oxide, niobium oxide, zirconium phosphate-based ceramic, willemite, β-eucryptite, and β-quartz solid solution are preferably used. Those refractory filler powders each have a low thermal expansion coefficient and a high mechanical strength, and besides are each well compatible with the bismuth-based glass.

The average particle diameter D₅₀ of the refractory filler powder is preferably less than 2 μm, particularly preferably less than 1.5 μm. When the average particle diameter D₅₀ of the refractory filler powder is less than 2 μm, the surface smoothness of the sealing material layer is improved, and the average thickness of the sealing material layer is easily controlled to less than 10 μm. As a result, the accuracy of the laser sealing can be improved.

The refractory filler powder has a 99% particle diameter D₉₉ of preferably less than 5 μm or 4 μm or less, particularly preferably 3 μm or less. When the 99% particle diameter D₉₉ of the refractory filler powder is less than 5 μm, the surface smoothness of the sealing material layer is improved, and the average thickness of the sealing material layer is easily controlled to less than 10 μm. As a result, the accuracy of the laser sealing can be improved. Herein, the terms “average particle diameter D₅₀” and “99% particle diameter D₉₉” each refer to a value measured by laser diffractometry on a volume basis.

The sealing material may further comprise a laser absorber in order to improve the light absorption properties, but the laser absorber has an action of accelerating the devitrification of the bismuth-based glass. Therefore, the content of the laser absorber is preferably from 1 vol % to 15 vol % or from 3 vol % to 12 vol %, particularly preferably from 5 vol % to 10 vol %. When the content of the laser absorber is too large, the glass is liable to devitrify at the time of laser sealing. As the laser absorber, a Cu-based oxide, an Fe-based oxide, a Cr-based oxide, a Mn-based oxide, or a spinel-type composite oxide thereof may be used. In particular, from the viewpoint of compatibility with the bismuth-based glass, a Mn-based oxide is preferred.

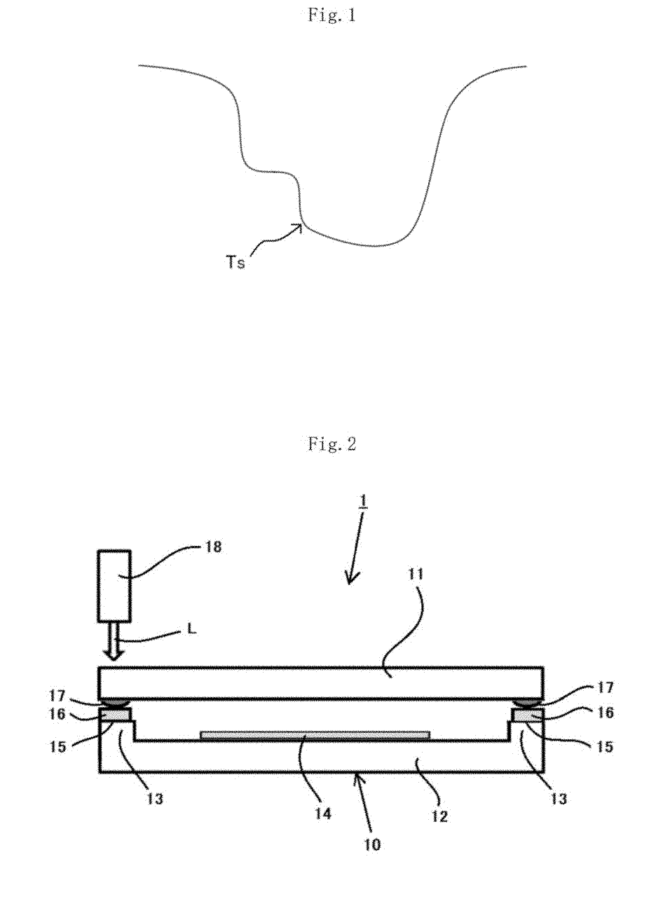

The softening point of the sealing material is preferably 500° C. or less or 480° C. or less, particularly preferably 450° C. or less. When the softening point is too high, it becomes difficult to increase the surface smoothness of the sealing material layer. The lower limit of the softening point is not particularly set. However, in consideration of the thermal stability of the glass, the softening point is preferably 350° C. or more. Herein, the term “softening point” refers to the fourth inflection point measured with a macro-type DTA apparatus, and corresponds to Ts in FIG. 1.

The thermal expansion coefficient of the sealing material layer is preferably from 60×10⁻⁷/° C. to 95×10⁻⁷/° C. or from 65×10⁻⁷/° C. to 82×10⁻⁷/° C. particularly preferably from 70×10⁻⁷/° C. to 76×10⁻⁷/° C. With this, the thermal expansion coefficient of the sealing material layer matches the thermal expansion coefficients of the glass cover and the sintered glass-containing layer, and hence a stress remaining in the sealed sites is reduced.

In the method of producing a hermetic package of the present invention, a ratio of (thickness of the sintered glass-containing layer)/(thickness of the sealing material layer) is controlled to preferably 0.5 or more or more than 1.0, particularly preferably more than 1.5. When the thickness of the sintered glass-containing layer is too small as compared to the thickness of the sealing material layer, heat is liable to be dissipated through the aluminum nitride base at the time of laser sealing, and hence the efficiency of the laser sealing is liable to be reduced.

Further, a ratio of (thermal expansion coefficient of the sintered glass-containing layer)/(thermal expansion coefficient of the aluminum nitride base) is controlled to preferably from 0.6 to 1.4 or from 0.8 to 1.2, particularly preferably from 0.9 to 1.1. When the ratio of (thermal expansion coefficient of the sintered glass-containing layer)/(thermal expansion coefficient of the aluminum nitride base) is outside the above-mentioned range, an improper stress is liable to remain in the sintered glass-containing layer, and cracks are liable to occur in the sintered glass-containing layer.

In the method of producing a hermetic package of the present invention, the sealing material layer is preferably formed by applying and sintering a sealing material paste. With this, the dimensional accuracy of the sealing material layer can be improved. In this case, the sealing material paste is a mixture of the sealing material and a vehicle. In addition, the vehicle generally comprises a solvent and a resin. The resin is added for the purpose of adjusting the viscosity of the paste. In addition, a surfactant, a thickener, or the like may also be added thereto as required. The produced sealing material paste is applied onto a surface of the glass cover by means of a coating machine, such as a dispenser or a screen printing machine.

The sealing material paste is preferably applied in a frame shape along a peripheral end edge region of the glass cover. With this, an area through which ultraviolet light or the like is transmitted can be increased.

The sealing material paste is generally produced by kneading the sealing material and the vehicle with a triple roller or the like. The vehicle generally contains a resin and a solvent. As the resin to be used in the vehicle, there may be used an acrylic acid ester (acrylic resin), ethylcellulose, a polyethylene glycol derivative, nitrocellulose, polymethyistyrene, polyethylene carbonate, polypropylene carbonate, a methacrylic acid ester, and the like. As the solvent to be used in the vehicle, there may be used N,N′-dimethyl formamide (DMF), α-terpineol, a higher alcohol, γ-butyrolactone (γ-BL), tetralin, butylcarbitol acetate, ethyl acetate, isoamyl acetate, diethylene glycol monoethyl ether, diethylene glycol monoethyl ether acetate, benzyl alcohol, toluene, 3-methoxy-3-methylbutanol, triethylene glycol monomethyl ether, triethylene glycol dimethyl ether, dipropylene glycol monomethyl ether, dipropylene glycol monobutyl ether, tripropylene glycol monomethyl ether, tripropylene glycol monobutyl ether, propylene carbonate, dimethyl sulfoxide (DMSO), N-methyl-2-pyrrolidone, and the like.

Various glasses may be used as the glass cover. For example, alkali-free glass, borosilicate glass, or soda lime glass may be used. In particular, in order to increase light transmissivity in an ultraviolet wavelength region, a low-iron-containing glass cover (having a content of Fe₂O₃ of 0.015 mass % or less, particularly less than 0.010 mass % in a glass composition) is preferably used.

The thickness of the glass cover is preferably from 0.01 mm to 2.0 mm or from 0.1 mm to 1 mm, particularly preferably from 0.2 mm to 0.7 mm. With this, thinning of the hermetic package can be achieved. In addition, the light transmissivity in the ultraviolet wavelength region can be increased.

A difference in thermal expansion coefficient between the sealing material layer and the glass cover is preferably less than 40×10⁻⁷/° C., particularly preferably 25×10⁻⁷/° C. or less. A difference in thermal expansion coefficient between the sealing material layer and the sintered glass-containing layer is preferably less than 40×10⁻⁷/° C., particularly preferably 25×10⁻⁷/° C. or less. When the differences in thermal expansion coefficient are too large, a stress remaining in the sealed sites is improperly increased, and there is a risk in that the long-term reliability of the hermetic package may be reduced.

The method of producing a hermetic package of the present invention comprises a step of arranging the aluminum nitride base and the glass cover so that the sintered glass-containing layer and the sealing material layer are brought into contact with each other. In this case, the glass cover may be arranged below the aluminum nitride base, but from the viewpoint of the efficiency of the laser sealing, the glass cover is preferably arranged above the aluminum nitride base.

The method of producing a hermetic package of the present invention comprises a step of irradiating the sealing material layer with laser light from a glass cover side to soften and deform the sealing material layer, to thereby hermetically seal the sintered glass-containing layer and the sealing material layer with each other to obtain a hermetic package.

Various lasers may be used as the laser. In particular, a semiconductor laser, a YAG laser, a CO laser, an excimer laser, and an infrared laser are preferred because those lasers are easy to handle.

An atmosphere for performing the laser sealing is not particularly limited. An air atmosphere or an inert atmosphere, such as a nitrogen atmosphere, may be adopted.

At the time of laser sealing, when the glass cover is preheated at a temperature higher than or equal to 100° C. and lower than or equal to the temperature limit of the light emitting device or the like in the aluminum nitride base, the breakage of the glass cover owing to thermal shock can be suppressed. In addition, when an annealing laser is radiated from the glass cover side immediately after the laser sealing, the cracks in the glass cover owing to thermal shock can be suppressed.

The laser sealing is preferably performed under a state in which the glass cover is pressed. With this, the sealing material layer can be softened and deformed acceleratedly at the time of laser sealing.

A hermetic package of the present invention comprises an aluminum nitride base and a glass cover, wherein the aluminum nitride base comprises a base part and a frame part formed on the base part, wherein the aluminum nitride base has formed, on a top of the frame part thereof, a sintered glass-containing layer substantially free of bismuth-based glass, wherein the glass cover has formed thereon a sealing material layer containing bismuth-based glass and refractory filler powder, and wherein the sintered glass-containing layer and the sealing material layer are hermetically integrated with each other under a state in which the sintered glass-containing layer and the sealing material layer are arranged so as to be brought into contact with each other. The technical features of the hermetic package of the present invention have already been described in the description section of the method of producing a hermetic package of the present invention. Therefore, in this case, for convenience, the detailed description thereof is omitted.

Now, the present invention is described with reference to the drawings. FIG. 2 is a conceptual sectional view for illustrating one embodiment of the present invention. A hermetic package (ultraviolet LED package) 1 comprises an aluminum nitride base 10 and a glass cover 11. The aluminum nitride base 10 comprises a base part 12, and further a frame part 13 on a peripheral end edge of the base part 12. In addition, an ultraviolet LED device 14 is housed inside the frame part 13 of the aluminum nitride base 10. Moreover, a sintered glass-containing layer 16 is formed on a top 15 of the frame part 13. The surface of the sintered glass-containing layer 16 is subjected to polishing treatment in advance, and the sintered glass-containing layer 16 has a surface roughness Ra of 0.15 μm or less. Moreover, the width of the sintered glass-containing layer 16 is slightly smaller than the width of the frame part 13. Further, the sintered glass-containing layer 16 is formed by sintering a glass-containing film formed of ZnO-based glass powder through irradiation with laser light. Electrical wiring (not shown) configured to electrically connect the ultraviolet LED device 14 to an outside is formed in the aluminum nitride base 10.

A sealing material layer 17 in a frame shape is formed on the surface of the glass cover 11. The sealing material layer 17 contains bismuth-based glass and refractory filler powder. Moreover, the width of the sealing material layer 17 is slightly smaller than the width of the sintered glass-containing layer 16. Further, the thickness of the sealing material layer 17 is slightly smaller than the thickness of the sintered glass-containing layer 16.

Laser light L output from a laser irradiation apparatus 18 is radiated from a glass cover 11 side along the sealing material layer 17. With this, the sealing material layer 17 softens and flows to react with the sintered glass-containing layer 16, and then hermetically seal the aluminum nitride base 10 and the glass cover 11 with each other. Thus, a hermetic structure of the hermetic package 1 is formed.

### EXAMPLES

Now, the present invention is described in detail by way of Examples. The following Examples are merely illustrative. The present invention is by no means limited to the following Examples.

First, a sealing material was produced. The material composition of the sealing material is shown in Table 1. The bismuth-based glass comprises as a glass composition, in terms of mol %, 36.9% of Bi₂O₃, 25.8% of B₂O₃, 16.6% of ZnO, 14.1% of CuO, 0.7% of Fe₂O₃, and 5.9% of BaO, and has particle sizes shown in Table 1.

TABLE 1

| Bismuth-based glass (vol %) | | 69 |
|---|---|---|
| Refractory filler (vol %) | | 24 |
| Laser absorber (vol %) | | 7 |
| Bismuth-based glass particle size (μm) | D₅₀ | 1.0 |
| | D₉₉ | 3.2 |
| Refractory filler particle size (μm) | D₅₀ | 1.0 |
| | D₉₉ | 2.8 |

| | |
|---|---|
| Glass transition point (° C.) | 382 |
| Softening point (° C.) | 454 |
| Thermal expansion coefficient [30-300° C.] (×10⁻⁷/° C.) | 80 |

The above-mentioned bismuth-based glass, refractory filler powder, and laser absorber were mixed at a ratio shown in Table 1 to produce a sealing material. Cordierite having particle sizes shown in Table 1 was used as the refractory filler powder. A Mn—Fe—Al-based pigment was used as the laser absorber. The Mn—Fe—Al-based composite oxide had an average particle diameter D₅₀ of 1.0 μm and a 99% particle diameter Ds of 2.5 μm. The sealing material was measured for a glass transition point, a softening point, and a thermal expansion coefficient. The results are shown in Table 1.

The glass transition point refers to a value measured with a push-rod-type TMA apparatus.

The softening point refers to a value measured with a macro-type DTA apparatus. The measurement was performed under an air atmosphere in the range of from room temperature to 600° C. at a temperature increase rate of 10° C./min.

The thermal expansion coefficient refers to a value measured with a push-rod-type TMA apparatus. The range of measurement temperatures is from 30° C. to 300° C.

Next, a sealing material layer in a frame shape was formed on the peripheral end edge of a glass cover (measuring 3 mm in length×3 mm in width×0.2 mm in thickness, an alkali borosilicate glass substrate, thermal expansion coefficient: 41×10⁻⁷/° C.) through use of the sealing material. Specifically, first, the sealing material shown in Table 1, a vehicle, and a solvent were kneaded so as to achieve a viscosity of about 100 Pa·s (25° C., shear rate: 4), and then further kneaded with a triple roll mill until powders were homogeneously dispersed, to thereby provide a paste. A vehicle obtained by dissolving an ethyl cellulose resin in a glycol ether-based solvent was used as the vehicle. Next, the resultant sealing material paste was printed in a frame shape with a screen printing machine along the peripheral end edge of the glass cover. Further, the sealing material paste was dried at 120° C. for 10 minutes under an air atmosphere, and then fired at 500° C. for 10 minutes under an air atmosphere. Thus, a sealing material layer having a thickness of 5 μm and a width of 300 μm was formed on the glass cover.

In addition, an aluminum nitride base (measuring 3 mm in length×3 mm in width×0.7 mm in thickness of a base part, thermal expansion coefficient: 46×10⁻⁷/° C.) was prepared, and a deep ultraviolet LED device was housed inside a frame part of the aluminum nitride base. The frame part has a frame shape having a width of 600 μm and a height of 400 μm, and is formed along the peripheral end edge of the base part of the aluminum nitride base.

Subsequently, a sintered glass-containing layer was formed on the frame part of the aluminum nitride base through use of ZnO-based glass powder (GP-014 manufactured by Nippon Electric Glass Co., Ltd., thermal expansion coefficient: 43×10⁻⁷/° C.). Specifically, first, the ZnO-based glass powder, a vehicle, and a solvent were kneaded so as to achieve a viscosity of about 100 Pa·s (25° C., shear rate: 4), and then further kneaded with a triple roll mill until powders were homogeneously dispersed, to thereby provide a paste. A vehicle obtained by dissolving an ethyl cellulose resin in a glycol ether-based solvent was used as the vehicle. Next, the resultant glass-containing paste was printed on the frame part with a screen printing machine. Further, the resultant glass-containing film was irradiated with a CO₂ laser at a wavelength of 10.6 μm and 7 W. Thus, a sintered glass-containing layer having a thickness of 20 μm and a width of 500 μm was formed on the frame part of the aluminum nitride base.

Finally, the aluminum nitride base and the glass cover were arranged so that the sintered glass-containing layer and the sealing material layer were brought into contact with each other. After that, a semiconductor laser at a wavelength of 808 nm and 5 W was radiated to the sealing material layer from a glass cover side to soften and deform the sealing material layer, to thereby hermetically integrate the sintered glass-containing layer and the sealing material layer with each other. Thus, a hermetic package was obtained.

The resultant hermetic package was subjected to a pressure cooker test (highly accelerated temperature and humidity stress test: HAST test). After that, the neighborhood of the sealing material layer was observed, and as a result, transformation, cracks, peeling, and the like were not observed at all. The conditions of the HAST test are 121° C., a humidity of 100%, 2 atm, and 24 hours.

### INDUSTRIAL APPLICABILITY

The hermetic package of the present invention is suitable for a hermetic package having mounted therein an ultraviolet LED device. Other than the above, the hermetic package of the present invention is also suitably applicable to a hermetic package configured to house a resin or the like having dispersed therein quantum dots, and the like.

### REFERENCE SIGNS LIST

1 hermetic package (ultraviolet LED package)
10 aluminum nitride base
11 glass cover
12 base part
13 frame part
14 ultraviolet LED device
15 top of frame part
16 sintered glass-containing layer
17 sealing material layer
18 laser irradiation apparatus
L laser light

1. A method of producing a hermetic package, comprising the steps of:
preparing an aluminum nitride base, and forming a sintered glass-containing layer on the aluminum nitride base;
preparing a glass cover, and forming a sealing material layer on the glass cover;
arranging the aluminum nitride base and the glass cover so that the sintered glass-containing layer and the sealing material layer are brought into contact with each other; and
irradiating the sealing material layer with laser light from a glass cover side to soften and deform the sealing material layer, to thereby hermetically seal the sintered glass-containing layer and the sealing material layer with each other to obtain a hermetic package.

2. The method of producing a hermetic package according to claim 1, wherein a width of the sintered glass-containing layer is larger than a width of the sealing material layer.

3. The method of producing a hermetic package according to claim 1, wherein a ratio of (thickness of the sintered glass-containing layer)/(thickness of the sealing material layer) is controlled to 0.5 or more.

4. The method of producing a hermetic package according to claim 1, wherein a ratio of (thermal expansion coefficient of the sintered glass-containing layer)/(thermal expansion coefficient of the aluminum nitride base) is controlled to 0.6 or more and 1.4 or less.

5. The method of producing a hermetic package according to claim 1, wherein the forming a sintered glass-containing layer comprises forming a glass-containing film on the aluminum nitride base, followed by irradiating the glass-containing film with laser light to sinter the glass-containing film.

6. The method of producing a hermetic package according to claim 1, wherein the aluminum nitride base to be used comprises a base part and a frame part formed on the base part, and the sintered glass-containing layer is formed on a top of the frame part.

7. The method of producing a hermetic package according to claim 1, further comprising a step of polishing a surface of the sintered glass-containing layer.

8. A hermetic package, comprising an aluminum nitride base and a glass cover,
wherein the aluminum nitride base comprises a base part and a frame part formed on the base part,
wherein the aluminum nitride base has formed, on a top of the frame part thereof, a sintered glass-containing layer substantially free of bismuth-based glass,
wherein the glass cover has formed thereon a sealing material layer containing bismuth-based glass and refractory filler powder, and
wherein the sintered glass-containing layer and the sealing material layer are hermetically integrated with each other under a state in which the sintered glass-containing layer and the sealing material layer are arranged so as to be brought into contact with each other.

9. The hermetic package according to claim 8, wherein a width of the sintered glass-containing layer is larger than a width of the sealing material layer.

10. The hermetic package according to claim 8, wherein a ratio of (thickness of the sintered glass-containing layer)/(thickness of the sealing material layer) is 0.5 or more.

11. The hermetic package according to claim 8, wherein a ratio of (thermal expansion coefficient of the sintered glass-containing layer)/(thermal expansion coefficient of the aluminum nitride base) is 0.6 or more and 1.4 or less.

12. The hermetic package according to claim 8, wherein the hermetic package has housed, inside the frame part of the aluminum nitride base, an ultraviolet LED device.
